(19) United States
(12) Patent Application Publication
(10) Pub. No.: US 2016/0300915 A1
(43) Pub. Date: Oct. 13, 2016

(54) METHOD FOR FABRICATING NANOGAP ELECTRODES, NANOGAP ELECTRODES ARRAY, AND NANODEVICE WITH THE SAME

(71) Applicants: Yutaka Majima, Yokohama-shi (JP); Toshiharu Teranishi, Tsukuba-shi (JP); Taro Muraki, Tokyo (JP); Daisuke Tanaka, Tsukuba-shi (JP)

(72) Inventors: Yutaka Majima, Yokohama-shi (JP); Toshiharu Teranishi, Tsukuba-shi (JP); Taro Muraki, Tokyo (JP); Daisuke Tanaka, Tsukuba-shi (JP)

(73) Assignee: JAPAN SCIENCE AND TECHNOLOGY AGENCY, Kawaguchi-shi (JP)

(21) Appl. No.: 15/069,879

(22) Filed: Mar. 14, 2016

Related U.S. Application Data
(62) Division of application No. 14/003,679, filed on Nov. 11, 2013, now abandoned.

(30) Foreign Application Priority Data
Mar. 8, 2011 (JP) 2011-050894

(51) Int. Cl. H01L 29/41; H01L 29/66; H01L 21/288; H01L 29/76

(52) U.S. Cl. CPC H01L 29/413; H01L 29/7613; H01L 29/66439; H01L 21/288

(57) ABSTRACT

A substrate 1 having metal layers 2A and 2B arranged to form a gap is dipped in an electroless plating solution mixed an electrolyte solution including metal ions with a reducing agent and a surfactant. Metal ions are reduced by the reducing agent to be precipitated on the metal layers 2A and 2B, and the surfactant is adhered to a surface of the metal on the metal layers, thereby forming a pair of electrodes 4A, 4B to be controlled to have a nanometer sized gap. These steps enable to provide a method for fabricating nanogap electrodes, a nanogap electrodes array, and a nanodevice with the same.

This application is a divisional of U.S. application Ser. No. 14/003,679, filed on Sep. 6, 2013, which is a National Stage of International Application No. PCT/JP2012/055002, filed on Feb. 28, 2012, which claims priority to Japanese priority application No. 2011-050894 filed on Mar. 8, 2011, which are hereby incorporated by reference.

### TECHNICAL FIELD

The present invention relates to a method for fabricating nanogap electrodes, a nanogap electrodes array, and a nanodevice with the same.

### BACKGROUND ART

It is a highly integrated VLSI system accompanying microfabrication of CMOS and a rapid growth in the field of semiconductor device such as DRAM and NAND flash memory that supports the advanced information society. Development of higher integration density, i.e., microfabrication of minimum processing size, has improved performance and functionality of electronic devices. On the other hand, the microfabrication brings about significant technical problems such as a short channel effect, velocity saturation, quantum effect, and so on.

In order to solve these problems, the microfabrication technology such as multi-gate structure, a high-K gate insulating film has been studied to leverage up to the maximum extent possible. Aside from these top-down microfabrication studies, there is a field of study with a fresh perspective, e.g., nanoelectronics, molecular nanoelectronics. The nanoelectronics is a new field of study to utilize a quantum effect of a single-electron island and a double tunnel junction to block electrons: incorporating nanoparticle to be a single-electron island in a three-terminal element via a double tunnel junction to develop a functionality as a device using a gate modulation (Non-Patent Literature 1). The molecular nanoelectronics is also a new field of study to utilize a molecule-sized quantum effect and a molecule-specific functionality: incorporating functionalized molecules in an element to develop functionality as a device (Non-Patent Literatures 2 and 3). The tunnel effect is the most representative one among the quantum effects: an electron wave function with lower energy than potential barrier goes into the barrier and, if the width of barrier is narrow, the function goes through the barrier with finite probability. This phenomenon is considered as one of possible cause of a leakage current due to the microfabrication of device. The nanoelectronics and molecular nanoelectronics are studied to effectively control this quantum effect as a device. This field of study is introduced as one of element technologies in the new explored element of The International Technology Roadmap for Semiconductors (ITRS) in 2009, and is the focus of much attention (Non-Patent Literature 4).

Furthermore, in combination with the top-down method, the method for fabricating the nanogap electrodes and the nanogap electrodes fabricated using this method makes it possible to fabricate a device difficult to be achieved using the top-down method only, e.g., a transistor with a channel length of 5 nm or under.

For creating such a device, it is important to fabricate a structure enabling electric contact between a nanometer-sized single-electron island or a molecule with the electrodes, i.e., “nanogap electrodes”. All the previously reported methods used for fabricating nanogap electrodes have a problem: mechanical break junction method to break a thin line by a mechanical stress (Non-Patent Literature 5 and 6) allows an accurate picometer-order, however, it is not good for integration; electro-migration method is a comparatively easy one, (Non-Patent Literature 7 and 8), however, the yield ratio is low and fine metal particles between the nanogaps are often problematic for measurement when breaking a line; other methods having a good accuracy is not desirable for integration, still others require an extremely low temperature environment to prevent gold migration or need long processing time (Non-Patent Literature 9 to 14).

In order to fabricate nanogap electrodes with a high yield ratio, the inventors of the present invention focused on an autocatalytic electroless gold plating method using iodine tincture. So far, the inventors have disclosed the plating method as the method to easily fabricate nanogap electrodes having a plurality of gap separations of 5 nm or less at room temperature with a high yield ratio (Non-Patent Literature 15). FIG. 28 is a view showing a dispersion of a nanogap separation controlled to have a length not exceeding 5 nm using the autocatalytic electroless gold plating method using iodine tincture. In FIG. 28, the horizontal and vertical axis respectively indicates gap separation nm and the number of gap separation. The standard deviation of the nanogap separation in this method is 1.7 nm.

### CITATION LIST

### Non-Patent Literature

Non-Patent Literature 1: F. Kuemmeth, K. I. Bolotin, S. Shi, and D. C. Ralph, Nano Lett., 8, 12 (2008).

Non-Patent Literature 2: M. H. Jo, J. E. Grose, K. Baheti, M. Deshmukh, J. J. Sokol, E. M. Rumberger, D. N. Hendrickson, J. R. Long, H. Park, and D. C. Ralph, Nano Letti., 6, 2014 (2006).

Non-Patent Literature 3: Y. Yasutake, Z. Shi, T. Okazaki, H. Shinohara, and Y. Majima, Nano Lett. 5, 1057 (2005).

Non-Patent Literature 4: ITRS Homepage, URL: HYPERLINK “http: //www.itrs.net/”http://www.itrs.net/

Non-Patent Literature 5: L. Gruter, M. T. Gonzalez, R. Huber, M. Calame, and C. Schonenberger, Small, 1, 1067 (2005).

Non-Patent Literature 6: J. J. Parks, A. R. Champagne, G. R. Hutchison, S. Flores-Torres, H. D. Abuna, and D. C. Ralph, Phys. Rev. Lett., 99, 026001 (2007).

Non-Patent Literature 7: T. Taychatanapat, K. I. Bolotin, F. Kuemmeth, and D. C. Ralph, Nano. Lett., 7, 652 (2007).

Non-Patent Literature 8: K. I. Bolotin, F. Kuemmeth, A. N. Pasupathy, and D. C. Ralph, Appl. Phys Lett, 84, 16 (2004).

Non-Patent Literature 9: S. Kubatkin, A. Danilov, M. Hjort, J. Cornil, J. L. Bredas, N. S. Hansen, P. Hedegard and T. Bjornholm, Nature, 425, 698 (2003).

Non-Patent Literature 10: K. Sasao, Y. Azuma, N. Kaneda, E. Hase, Y. Miyamoto, and Y. Majima, Jpn. J. Appl. Phys., Part2 43, L337 (2004).

Non-Patent Literature 11: Y. Kashimura, H. Nakashima, K. Furukawa, and K. Torimitsu, Thin Solid Films, 438-439, 317 (2003).

Non-Patent Literature 12: Y. B. Kervennic, D. Vanmaekelbergh, L. P. Kouwenhoven, and H. S. J. Van der Zant, Appl. Phys. Lett., 83, 3782 (2003).

Non-Patent Literature 13: M. E. Anderson, M. Mihok, H. Tanaka, L. P. Tan, M. K. Horn, G. S. McCarty, and P. S. Weiss, Adv. Mater., 18, 1020 (2006).

Non-Patent Literature 14: R. Negishi, T. Hasegawa, K Terabe, M. Aono, T. Ebihara, H. Tanaka, and T. Ogawa, Appl. Phys. Lett., 88, 223111 (2006).

Non-Patent Literature 15: Y. Yasutake, K. Kono, M. Kanehara, T. Teranishi, M. R. Buitelaar, C. G. Smith, and Y. Majima, Appl. Phys. Lett., 91, 203107 (2007).

Non-Patent Literature 16: Mallikarjuma N. Nadagouda, and Rajender S. Varma, American Chemical Soviety Vol. 7, No. 12 2582-2587 (2007).

Non-Patent Literature 17: H. Zhang, Y Yasutake, Y. Shichibu, T. Teranishi, Y. Manjima, Physical Review B 72, 205441,205441-1-205441-7, (2005).

Non-Patent Literature 18: Yuhsuke Yasutake, Zujin Shi, Toshiya Okazaki, Hisanori Shinohara, Yutaka Majima, Nano Letters Vol. 5, No. 6 1057-1060, (2005).

### SUMMARY OF INVENTION

### Technical Problem

However, the previously described autocatalytic electroless gold plating method using iodine tincture does not make it always easy for an accurate control of the gap separation and a high productivity of gap electrodes with the desired gap separation.

Accordingly, a first objective of the present invention is to provide a method for fabricating nanogap electrodes enabling a dispersion control of nanogap separation; and a second objective of the present invention is to provide a dispersion-controlled nanogap electrodes array and a device using the same.

### Solution to Problem

The inventors have successfully control dispersion of a gap separation with more accuracy than ever before using a molecular length of surfactant molecule and completed the present invention.

Specifically, the inventors focused on a plating method using surfactant molecule for synthesizing nanoparticle as a protective group. As for surfactant molecule, for example, alkyltrimethylammonium bromide can be used. This surfactant molecule includes a straight alkyl chain and trimethylammonium group N(CH₃)₃, is attached to the alkyl chain, where all the hydrogen atoms in ammonium group are substituted with methyl group.

In order to achieve the above first objective, the present invention provides a method for fabricating nanogap electrodes, includes:

dipping a substrate in an electroless plating solution, the substrate having a pair of metal layers with a gap, the solution being mixed an electrolyte solution including metal ions with a reducing agent and a surfactant,

whereby the metal ions are reduced by the reducing agent, metal is precipitated on the metal layers, and the surfactant is adhered to a surface of the metal on the metal layers to form a pair of electrodes to be controlled to have a nanometer sized gap.

The present invention provides a method for fabricating nanogap electrodes, includes:

a first step of preparing a substrate having a pair of metal layers with a gap; and

a second step of dipping the substrate having the pair of electrodes in an electroless plating solution, the solution being mixed an electrolyte solution including metal ions with a reducing agent and a surfactant,

whereby the metal ions are reduced by the reducing agent, metal is precipitated on the metal layers, and the surfactant is adhered to a surface of the metal layers to form a pair of electrodes to be controlled to have a nanometer sized gap.

In order to achieve the above second objective, the present invention provides a nanogap electrodes array, includes: a plurality of pairs of electrodes having a nanogap separation, wherein the standard deviation of each nanogap separation is 0.5 nm to 0.6 nm or provides a nanodevice with the same.

### Advantageous Effects of Invention

According to the method for fabricating nanogap electrodes of the present invention, nanogap electrodes controlled to have a molecular length can be fabricated using electroless plating method in which surfactant molecules, i.e., protective group, are used as molecular ruler on an electrode surface. Moreover, the method of the present invention makes it possible to plate an initial nanogap electrodes fabricated by the top-down method using an electroless plating method using iodine tincture and perform a molecular ruler electrolytic plating after reducing some distance to control the gap separation with more accurate and higher yield ratio.

The nanogap electrodes obtained by the method of the present invention can provide a plurality of pairs of electrodes having a gap separation with the standard deviation of 0.5 to 0.6 nm and controlled with a high accuracy and a low dispersion by changing a molecular length of the surfactant molecule. Using the nanogap electrodes obtained by the present invention allows fabrication of a nanodevice with the nanogap electrodes with a high yield ratio, e.g., diode element, tunnel element, thermionic element, thermophotovoltaic element.

### BRIEF DESCRIPTION OF THE DRAWINGS

FIG. 1 (a) and FIG. 1 (b) are cross-sectional views schematically showing a method for fabricating nanogap electrodes according to the first embodiment of the present invention.

FIG. 2 (a) and FIG. 2 (b) are plan views schematically showing the method shown in FIG. 1 (a) and FIG. 1 (b).

FIG. 3 is a view schematically showing nanogap electrodes fabricated using the method shown in FIG. 1.

FIG. 4 is a view schematically showing a chemical structure of surfactant molecule CTAB, used as a molecular ruler.

FIG. 5 (a), FIG. 5 (b), and FIG. 5 (c) are views schematically showing an installation process of a single-electron island by a chemical bond using dithiol molecules for the nanogap electrodes fabricated using the methods shown in FIG. 1 (a), FIG. 1 (b), FIG. 2 (a), FIG. 2 (b), and FIG. 3.

FIG. 6 (a), FIG. 6 (b), FIG. 6 (c), and FIG. 6 (d) are plan views showing a fabrication process of a nanodevice having the nanogap electrodes according to the third embodiment of the present invention.

FIG. 7 (a), FIG. 7 (b), FIG. 7 (c), and FIG. 7 (d) are cross-sectional views showing a fabrication process of the nanodevice having the nanogap electrodes according to the third embodiment of the present invention.

FIG. 8 is a part of an SEM image observed after fabricating a plurality of pairs of electrodes regarding the examples 1 to 4.

FIG. 9 (a), FIG. 9 (b), FIG. 9 (c), and FIG. 9 (d) are an SEM image of nanogap electrodes fabricated by dipping a substrate with initial nanogap electrodes shown in FIG. 8 in a molecular ruler plating solution.

FIG. 10 (a) and FIG. 10 (b) are SEM images showing an example of the nanogap electrodes fabricated in the example 1.

FIG. 11 (a) and FIG. 11 (b) are SEM images showing an example of the nanogap electrodes fabricated in the example 2.

FIG. 12 (a) and FIG. 12 (b) are SEM images showing an example of the nanogap electrodes fabricated in the example 3.

FIG. 13 (a) and FIG. 13 (b) are SEM images showing an example of the nanogap electrodes fabricated in the example 4.

FIG. 14 is a view showing a distribution of gap dispersion in the plurality of pairs of gap electrodes fabricated in the example 1.

FIG. 15 is a view showing a distribution of gap dispersion in the plurality of pairs of gap electrodes fabricated in the example 2.

FIG. 16 is a view showing a distribution of gap dispersion in the plurality of pairs of gap electrodes fabricated in the example 3.

FIG. 17 is a view showing a distribution of gap dispersion in the plurality of pairs of gap electrodes fabricated in the example 4.

FIG. 18 is a view overlaying histograms respectively shown in FIGS. 14 to 17.

FIG. 19 is a graph plotting a two-chain length of surfactant molecules and the actual average.

FIG. 20 is a view showing a relation between a carbon number n and a gap separation in the surfactant.

FIG. 21 (a), FIG. 21 (b), and FIG. 21 (c) are SEM images showing nanogap electrodes fabricated in the example 5.

FIG. 22 is a view showing a histogram of nanogap electrodes at each stage of the fabrication in the example 5.

FIG. 23 is a view schematically showing a particle introduction of the single-electron device fabricated in the example 6.

FIG. 24 (a) is a general view and FIG. 24 (b) is an enlarged view respectively showing current-voltage characteristics of the single-electron device fabricated in the example 6 at liquid nitrogen temperature.

FIG. 25 is a view showing current-voltage characteristics of the single-electron device fabricated in the example 6 using a gate voltage as a parameter.

FIG. 26 is an SEM image of nanogap electrodes fabricated by dipping the substrate with initial nanogap electrodes in a molecular ruler plating solution in the example 7.

FIG. 27 is a view showing a histogram of the gap separation of the sample fabricated in the example 7.

FIG. 28 is a view showing a dispersion of a nanogap separation controlled to have a length not exceeding 5 nm by an autocatalytic electroless gold plating process using iodine tincture, described in the background art.

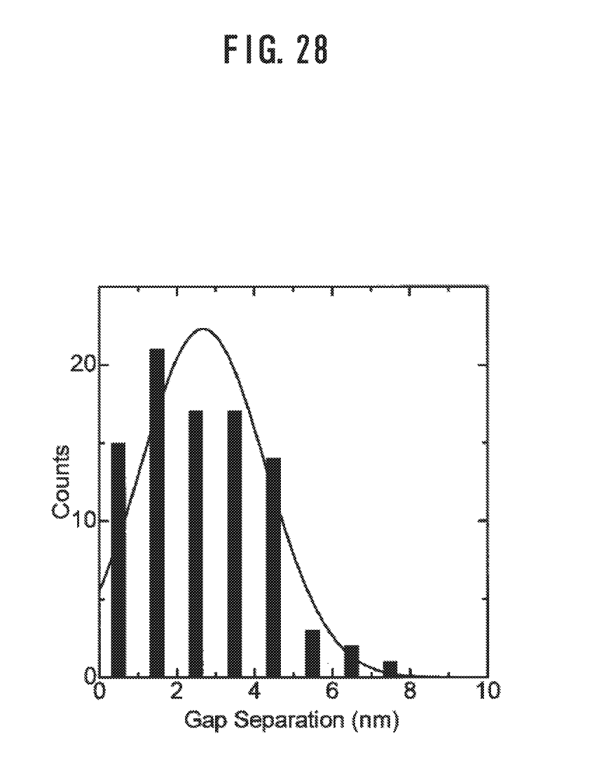

### REFERENCE SIGNS LIST

1: Substrate
1A: Semiconductor substrate
1B: Insulating film
2A, 2B, 2C, 2D: Metal layer (initial electrode)
3A, 3B, 3C, 3D: Metal layer (Electrode formed by plating)
4A, 4B: Electrode
5: Surfactant (molecular ruler)
5A, 5B: Self-assembled monolayer
6: Alkanedithiol
7: SAM hybrid film
8: Nanoparticles
8A: Au nanoparticle with alkanethiol protected
10: Nanogap electrodes
11: Semiconductor substrate
12: Insulating film
13: Substrate
14A, 14B: Metal layer
15: Insulating film
16: Metal film
17: Gate insulating film
18B: Metal layer
20: Gate electrode
21: Source electrode
22: Drain electrode

### DESCRIPTION OF EMBODIMENTS

Hereafter, embodiments of the present invention will be described with reference to the drawings. In the drawings, the same reference sign is used for the same or corresponding component.

### [The Method for Fabricating Nanogap Electrodes]

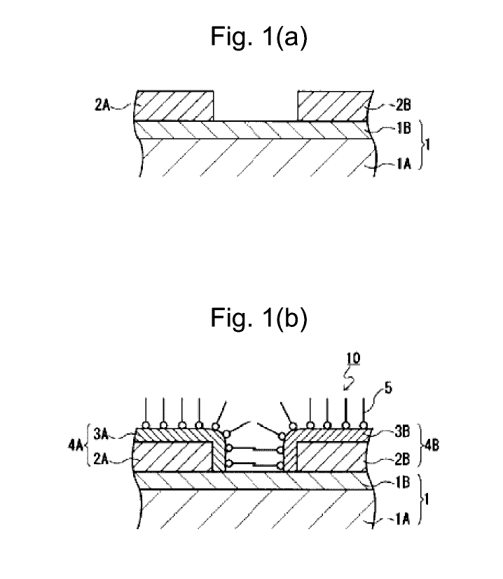

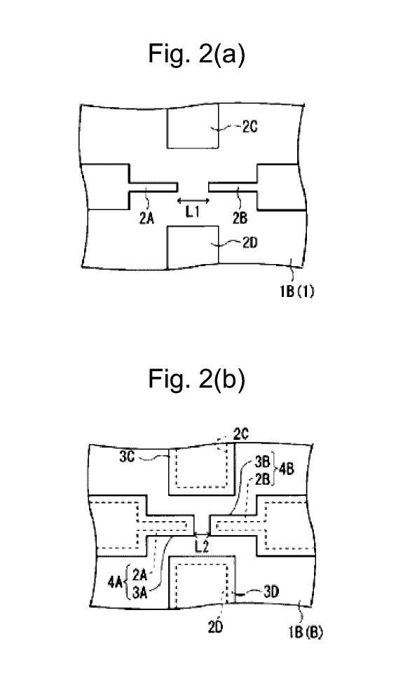

Hereafter, the method for fabricating an electrode structure with a nanogap separation according to the first embodiment of the present invention (hereafter, simply referred to as the method for fabricating a nanogap electrodes) will be fully described. FIG. 1 is a cross-sectional view schematically showing a method for fabricating nanogap electrodes according to the first embodiment of the present invention, and FIG. 2 is a plan view schematically showing the method shown in FIG. 1.

As shown in FIGS. 1(a) and 2(a), on a substrate 1, a pair of metal layers 2A and 2B is formed with a gap L1. The substrate 1 has a semiconductor substrate 1A on which an insulating film 1B is provided.

Next, the substrate 1 is dipped in an electroless plating solution. The electroless plating solution is fabricated by mixing an electrolyte solution including metal ions with a reducing agent and a surfactant. When the substrate 1 is dipped in the electroless plating solution, as shown in FIGS. 1(b) and 2(b), metal ions is reduced by the reducing agent and metal is precipitated on a surface of the metal layers 2A, 2B and turn into metal layers 3A, 3B. The gap between the metal layers 3A and 3B becomes narrow, a distance indicating L2, and the surfactant included in the electroless plating solution is chemically adsorbed on the metal layers 3A, 3B so that the surfactant controls a gap length (referred to as “gap separation”) to be a nanometer size.

Since the metal ions in the electrolyte solution are reduced by the reducing agent and metal is precipitated, this method is classified into an electroless plating method. Using this method, the metal layers 3A, 3B are formed on the metal layers 2A, 2B by plating to obtain a pair of electrodes 4A, 4B. Using the electroless plating method using surfactant molecules, i.e., protective group, as a molecular ruler (hereafter, referred to as “molecular ruler electroless plating method”), a pair of electrodes 10 with a nanogap separation (hereafter, referred to as “nanogap electrodes”) is fabricated on a surface of the electrodes 4A, 4B. The gap separation of nanogap electrodes is controlled to correspond to the molecular length.

As shown in FIG. 2(a), metal layers 2C, 2D are formed at the both sides of the metal layers 2A, 2B; as shown in FIG. 2(b), metal layers 3C, 3D as well as the metal layers 3A, 3B are formed on the metal layers 2C, 2D by plating, thereby the metal layer 2C and 3C may be used as side gate electrode. The metal layer 2D and 3D may be used as side gate electrode.

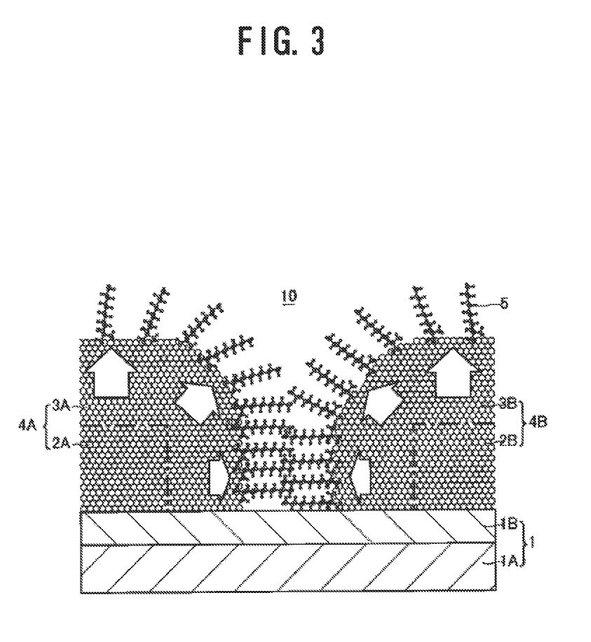

FIG. 3 is a view schematically showing nanogap electrodes fabricated by the method shown in FIG. 1. Along with the description of the fabricating method, the nanogap electrodes 10 according to the embodiment of the present invention will be fully described.

An insulating film (silicon dioxide film 1B) is formed on the semiconductor substrate 1A (Si substrate), and then initial nanogap electrodes (metal layers 2A, 2B) are formed on the substrate 1 (first step). The metal layers 2A, 2B may be structured by laminating an adhesive layer made of Ti, Cr, Ni, and others on the substrate 1 and another layer made of Au, Ag, Cu, and others on the adhesive layer.

Next, the electrolytic plating method is performed to form gold layers (metal layers 3A, 3B), at that time, the molecular ruler (molecules 5 in the surfactant) controls growth of the gold layers (second step).

This second step controls growth of the metal layers 3A, 3B, as a result, a gap between electrodes 4A and 4B is precisely controlled to be nanosized so that nanogap electrodes are fabricated. The arrows in the figure schematically indicate inhibition of the growth.

In the first step, the initial nanogap electrodes (metal layers 2A, 2B) are fabricated using the electron lithography technology (hereafter, referred to as “EB lithographic technology”), for example. The gap separation depends on the performance of EB lithographic technology and yield ratio but is in a range between 20 nm and 100 nm, for example. Fabricating the side gate electrodes in the first step also concurrently enables the gate electrodes to grow using the electroless plating method and to be closer to a single-electron island.

Next, the second step will be fully described.

The mixed plating solution includes a surfactant served as a molecular ruler and a solution in which precipitating positive metal ions are mixed, for example, a gold trichloride acid solution and a reducing agent. The mixed solution preferably includes some acids, as described later.

As a molecular ruler, for example, alkyltrimethylammonium bromide molecules, i.e., a surfactant, are used. Specifically, decyltrimethylammonium bromide (DTAB), lauryltrimethylammonium bromide (LTAB), myristyltrimethylammonium bromide (MTAB), cetyltrimethylammonium bromide (CTAB) are used as alkyltrimethylammonium bromide.

The molecular ruler is not limited to the above. Alkyltrimethylammonium halide, alkyltrimethylammonium chloride, alkyl trimethylammonium iodide, dialkyl dimethyl ammonium bromide, dialkyl dimethyl ammonium chloride, dialkyl dimethyl ammonium iodide, alkylbenzyldimethylammonium bromide, alkylbenzyldimethylammonium chloride, alkyl benzyl dimethyl ammonium iodide, alkylamine, N-methyl-1-alkyl-amine, N-methyl-1-dialkyl-amin, trialkyl amines, oleylamine, alkyl dimethyl phosphine, trialkyl phosphines, and alkylthiol, any one of these can be used. Further, a long chain aliphatic alkyl group is also not limited to alkyl group or alkylene group such as hexyl, octyl, decyl, dodecyl, tetradecyl, hexadecyl, octadecyl because the same effect is expected if it is a long chain aliphatic alkyl group.

As a molecular ruler, any one of the following other than DDAB (N,N,N,N′,N′,N′-hexamethyl-1,10-decandiammonium dibromide) may be used: hexamethonium bromide, N,N′-(1,20-icosanediyl) bis (trimethylaminium) dibromide, 1,1′-(decane-1,10-diyl) bis [4-aza-1-azoniabicyclo [2.2.2]octane]dibromide, propylditrimethylammonium chloride, 1,1′-dimethyl-4,4′-bipyridinium dichloride, 1,1′-dimethyl-4,4′-bipyridinium diiodide, 1,1′-diethyl-4,4′-bipyridinium dibromide, and 1,1′-diheptyl-4,4′-bipyridinium dibromide.

The electrolyte solution includes a gold trichloride acid solution, gold trichloride acid sodium solution, gold trichloride acid potassium solution, gold trichloride solution, and organic solvent in which gold trichloride acid ammonium salt is dissolved. The above ammonium salt can be used as ammonium salt, and as for the organic solvent, there are aliphatic hydrocarbon, benzene, toluene, chloromethane, dichloromethane, chloroform, carbon tetrachloride, and others.

As for the reducing agent, there are ascorbic acid, hydrazine, primary amine, secondary amine, primary alcohol, secondary alcohol, polyol (including diol), sodium sulfite, borohydride and hydroxylammonium chloride, lithium aluminum hydride, oxalic acid, formic acid, and others.

An acid with a comparatively weak reducing power, for example, ascorbic acid, achieves a reduction to zero-valent gold by self-catalytic plating used the electrode surface as a catalyst. If an acid with a stronger reducing power is used, a reduction is made at other than electrodes to generate many clusters. In fact, it is not preferable because fine gold particles are generated in the solution and gold cannot be selectively precipitated on the electrodes. If an acid with a weaker reducing power is used, a self-catalytic plating reaction is hardly occurred. Incidentally, cluster is a gold nanoparticle on which there is a core enabling electroless plating and formed on the core by plating.

L(+)-ascorbic acid is preferable to be used as a reducing agent because it has a weak reducing power among the above reducing agents to generate fewer clusters and to reduce the gold to zero-valent using the electrode surface as a catalyst.

It is preferable to mix an acid to inhibit generation of cluster in the electroless plating solution because it can dissolve clusters in an unstable condition of starting to form a core. Hydrochloric acid, nitric acid, acetic acid can be used.

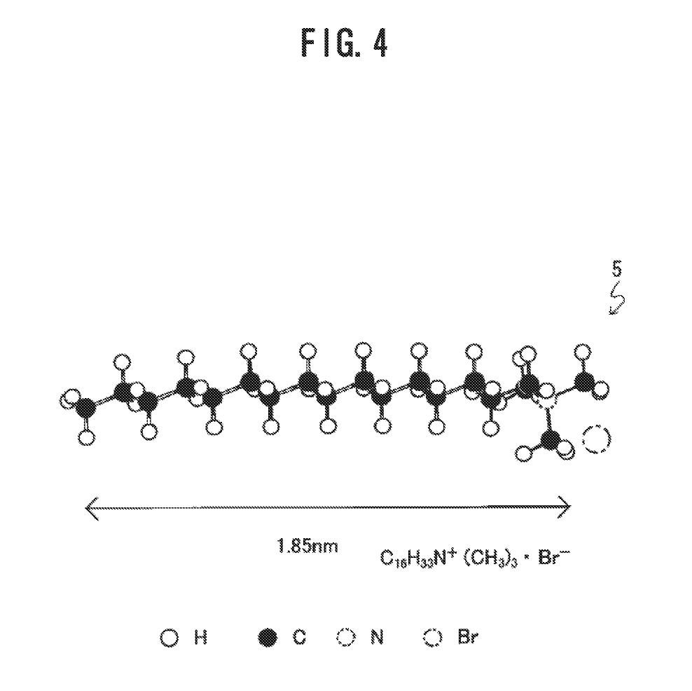

FIG. 4 is a view schematically showing a chemical structure of surfactant molecule (CTAB), used as a molecular ruler. CTAB is a C16 molecule, i.e., having an alkyl chain length of 16 straight chain carbons. The following four molecules are considered as one of the best embodiment: a derivative having a different alkyl chain; DTAB with an alkyl chain of C10, LTAB of C12, and MTAB of C14. These initial letters L, M, and C respectively stand for lauryl (12), myristyl (14), and cetyl (16).

The reason why the gold is electrolessly plated on the metal layers 2A, 2B and not precipitated on the SiO2 will be described. Since the autocatalytic electroless gold plating is used for the embodiment of the present invention, gold is precipitated on the gold electrode surface, i.e., the core, which enables reducing the gold to zero-valent using the gold electrodes as a catalyst due to a weak reducing power of ascorbic acid.

Further, pH and temperature of the plating solution depends on the surfactant type, especially a carbon number the straight chain, but approximately in the range between 25 and 90° C.; 2 and 3 pH. Over the range is not preferable because it becomes difficult to perform a gold plating.

The method for fabricating nanogap electrodes according to the embodiment of the present invention will be described.

Same as in the first embodiment, in the first step of the second embodiment, a pair of metal layers 2A, 2B are formed on a substrate 1 with an insulating film 1B. At that time, the above-described EB lithographic technology is used to form a pair of metal layers with some gap separation on the substrate 1. This “some” separation is determined dependent on the accuracy of the EB lithographic technology.

A gold foil is dissolved in an iodine tincture solution, that is, gold as [AuI4]-ion is dissolved. In the solution, a reducing agent, L(+)-ascorbic acid is added to perform an autocatalytic electroless gold plating on the gold electrode surface.

Next, the metal layers 2A, 2B are formed using an iodine electroless plating method, which allows the pair of metal layers 2A, 2B to be closely arranged at one surface of the substrate 1, i.e., the gap separation of initial electrodes (metal layers 2A, 2B) can be narrowed. For example, the metal layers 2A, 2B can be formed with a good accuracy of a few to about 10 nm separation.

Then, same as in the first embodiment, the substrate 1 is dipped in the electroless plating solution in the second step. The pair of metal layers 2A, 2B are arranged to be close to each other in the first step in the second embodiment, which allows the substrate 1 to be dipped in the electroless plating solution for a shorter time, i.e., the plating time can be shortened to inhibit a decrease of the yield ratio due to gold cluster forming.

On the contrary, if the pair of metal layers 2A, 2B are formed with a large separation in the first step, the substrate 1 needs to be dipped in the mixed solution for a longer time in the second step, i.e., a long plating time is required. In the molecular ruler electroless plating method, growth conditions of particles are referenced. A long plating time causes clusters to form. The gold clusters adhered to the peripheral surface of the electrodes result in a poor yield ratio. The second embodiment of the present invention enables inhibition of losing the yield ratio.

### [Nanogap Electrodes and the Device Using the Same]

Next, the nanogap electrodes fabricated by the method described in the first and second embodiment of the present invention will be described.

The nanogap electrodes array according to an embodiment of the present invention have a plurality pair of electrodes collaterally arranged with a nanogap and the standard deviation of the gap separation is in the predetermined range, 0.5 to 0.6 nm, later described in the example 1. In fact, low dispersion can be achieved.

Therefore, when one of the pairs is used as a source electrode and the other is used as a drain electrode, a side gate electrode provided at the both sides of the source electrode and drain electrode allows an efficient fabrication of various devices such as a single-electron device. A thermally-oxidized film of the insulating film 1B of the substrate 1 is used for a channel.

Hereafter, based on the nanogap electrodes 10 fabricated using the molecular ruler electroless plating method, fabrication of a single-electron device will be described. Further, a single-electron device using Au nanoparticle having organic molecules as a protective group will be described. An effectiveness evaluation of the gold nanogap electrodes fabricated using the electroless gold plating method will be also described. To begin with, a step for fixing particles between electrodes will be described.

In a single-electron device using Au nanoparticle having organic molecules as a protective group, the Au nanoparticle is fixed on, for example, a self-assembled monolayer between the gold nanogap electrodes by a chemical bonding using ligand exchange of alkanethiol-protected Au nanoparticle with dithiol molecules. The Coulomb blockade characteristics are observed at liquid nitrogen temperature.

Here is a full description.

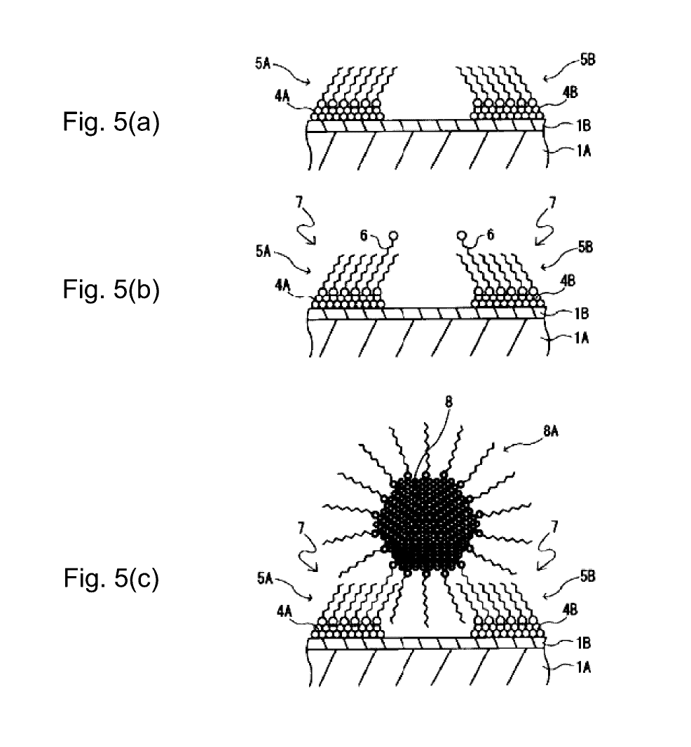

FIG. 5 is a view schematically showing an installation process of a single-electron island by a chemical bond using dithiol molecules for the nanogap electrodes 4A, 4B fabricated using the methods shown in FIGS. 1 to 3. As shown in FIG. 5(a), on the gold electrode surface (electrodes 4A, 4B), self-assembled monolayers (SAM) 5A, 5B are formed. Then, as shown in FIG. 5 (b), introduction of alkanedithiol 6 allows coordination of alkanedithiol at a SAM defect portion, and a SAM hybrid film 7 constituted of SAM and alkanethiol is formed. Then, Au nanoparticle with alkanethiol protected 8A is introduced. Then, as shown in FIG. 5 (c), Au nanoparticle 8 is chemically adsorbed on the self-assembled monolayers using ligand exchange of alkanethiol as a protective group in Au nanoparticles 8 with alkanedithiol in a mixed self-assembly monolayer 7, constituted of alkanethiol and alkanedithiol.

In this way, using self-assembly monolayers 6A, 6B, nanoparticle 8 are introduced as a single-electron island between the nanogap electrodes by a chemical adsorption so that a device using gold nanogap electrodes can be structured.

The nanogap electrodes shown in FIGS. 1 to 5 has a structure in which electrodes are horizontally arranged, however, embodiments of the present invention may have a laminated structure in which electrodes are vertically arranged.

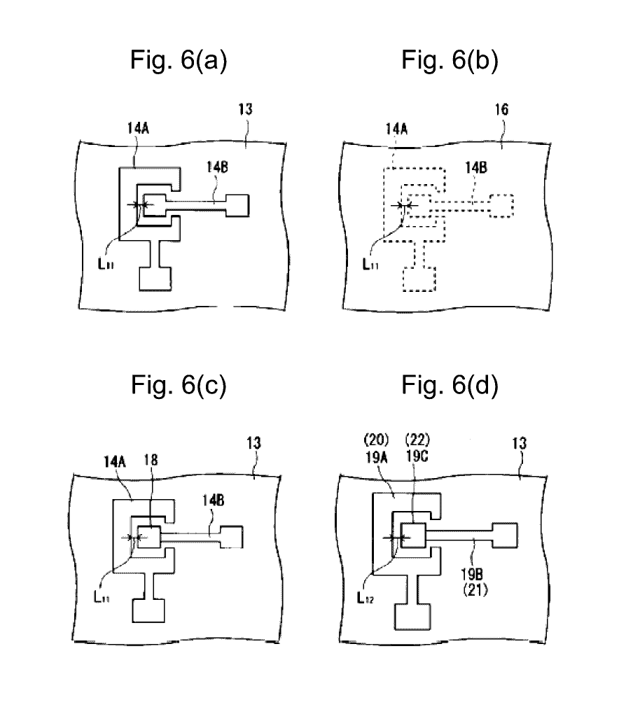

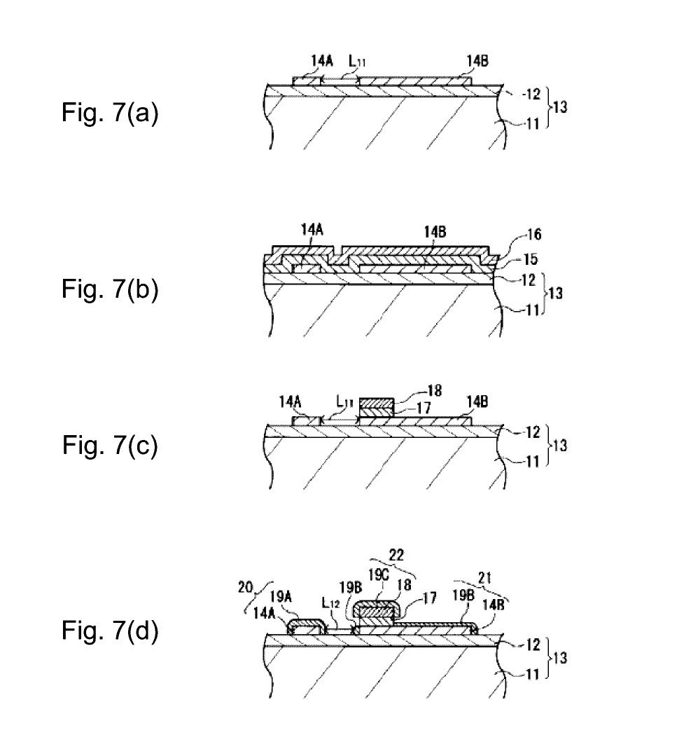

FIG. 6 is a plan view showing a fabrication process of a device with the nanogap electrodes according to the third embodiment of the present invention. FIG. 7 is a cross-sectional view showing a fabrication process of the device with the nanogap electrodes according to the third embodiment of the present invention.

First, to prepare a substrate 13: a semiconductor substrate 11 such as Si substrate on which an insulating film 12 such as SiO2 film is provided. Then, after forming a resist film on the substrate 13, to expose the substrate 13 with the resist film to perform a pattern formation to be the gate electrode and drain electrode using the EB lithography or optical lithography.

Next, to evaporate metal such as gold or copper which becomes a gate and source electrodes and to perform a liftoff, thereby forming metal layers 14A, 14B, to be a part of the gate electrode and source electrode (see FIGS. 6(a) and 7(a)). At that time, the distance between metal layers 14A and 14B is indicated as L11.

Next, to deposit an insulating film 15 made of SiO2 or SiN, for example, by plasma enhancement CVD (PECVD), then, to evaporate metal such as gold or copper to be the drain electrode to form a metal film 16 (see FIGS. 6(b) and 7(b)).

Then, after forming a resist film, exposing this sample to perform a pattern formation to be a shape of the drain electrode using the EB lithography or optical lithography.

Next, to perform a reactive ion etching (RIE) or chemical dry etching (CDE) until a metal layer 18B (a part of the drain electrode) and a gate insulating film 17 are formed. The etching should be vertically performed to the substrate 13 so that the metal layer 18B and the insulating film form a shape of a drain electrode until the surface of the formed source electrode comes out. Further, when using the EB lithography or optical lithography, the drain electrode must be smaller than the formed source electrode in consideration of misalignment of the exposure plus something extra. This process removes the insulating film and metal layers laminated on the metal layer 14A (a part of the drain electrode) to be exposed (see FIGS. 6(c) and 7(c)).

Next, to perform the molecular ruler electroless plating method only or, further to perform the iodine electroless plating method to reduce the gap between the source electrode and drain electrode. Performing the molecular ruler electroless plating method may be enough because the gate insulating film 17 has only about 10 nm thickness. The molecular ruler electroless plating method prompts a plating growth of edge of the metal layer 18B (a part of the drain electrode) in a horizontal direction, that of the metal layer 14B (a part of the source electrode) in a vertical direction, and that of metal layer 14A (a part of the gate electrode) in an inner direction (see FIGS. 6(d) and 7(d)). The grown films are respectively indicated as 19A, 19B, and 19C. Accordingly, each of the distance between the gate electrode 20, the source electrode 21, and the drain electrode 22 is reduced, for example, the distance L11 in FIGS. 6(a) and 7(a) becomes L12. Thus, the gate capacitance increases.

Next, as described with reference to the FIG. 5, to introduce nanoparticle. Finally, to form a passivation film and to open a die of the source electrode, drain electrode, and gate electrode, thereby completing a fabrication of a single-electron transistor.

As thus far described, the nanogap electrodes formed by the molecular ruler plating may be vertically laminated. The molecular ruler plating can thicken an insulator between the source electrode and drain electrode and reduce a leakage current. In addition, it is preferable to control the nanogap separation around the electrodes by the molecular ruler.

In the above embodiments, gold is used for an electrode material but other metals may be used, for example, copper can be a material of initial electrodes. In that case, the initial electrodes form copper electrodes using the EB lithography method or optical lithography method, and turn the surface portion of the copper electrode to copper chloride. Then, a surface of the copper chloride is covered with gold using gold chloride solution including an ascorbic acid as a reducing agent in the plating solution. The method is disclosed in Non-Patent Literature 16, for example. Specifically, to mix a surfactant alkyltrimethylammonium bromide CnH2n+1 [CH3] 3N+.·Br− to a gold trichloride acid solution, and add a reducing agent L(+)-ascorbic acid to perform an autocatalytic electroless gold plating on the gap electrodes. Then, nanogap electrodes with a gold surface are fabricated using the molecular ruler plating method.

Hereafter, it will be fully described with reference to examples that the method for fabricating nanogap electrodes according to the embodiments of the present invention enables a highly accurate and precise control of a nanogap separation.

### EXAMPLE 1

As an example 1, nanogap electrodes are fabricated as follows using the molecular ruler electroless plating method, described in the first embodiment.

First, a silicon substrate (substrate 1A) on which a silicon dioxide film (insulating film 1B) is thoroughly provided is prepared. Then the substrate 1 is coated with resist and a pattern of initial electrodes (metal layers 2A, 2B with 30 nm gap separation) is drawn using the EB lithographic technology. After development, a 2 nm-Ti film is evaporated by EB evaporation and, on the Ti film, 10 nm Au is evaporated so that initial gold nanogap electrodes (metal layers 2A, 2B) is fabricated. A plurality of pairs of metal layers 2A, 2B are provided on the same substrate 1.

Next, an electroless plating solution is prepared. 28 mL (milliliter) of 25 mM (millimole) alkyltrimethylammonium bromide is measured to be used as a molecular ruler. Then, 120 μL it (microliter) of 50 mM chlorauric acid solution is measured and added therein. 1 mL acetic acid as an acid and 3.6 mL of 0.1 mol L(+)-ascorbic acid as a reducing agent are added therein, and all are well stirred to be used as a plating solution.

In the example 1, DTAB molecules are used as alkyltrimethylammonium bromide.

The already fabricated substrate with gold nanogap electrodes is dipped in the electroless plating solution for about 30 minutes. Thereby, nanogap electrodes are fabricated using the molecular ruler electroless plating method in the example 1.

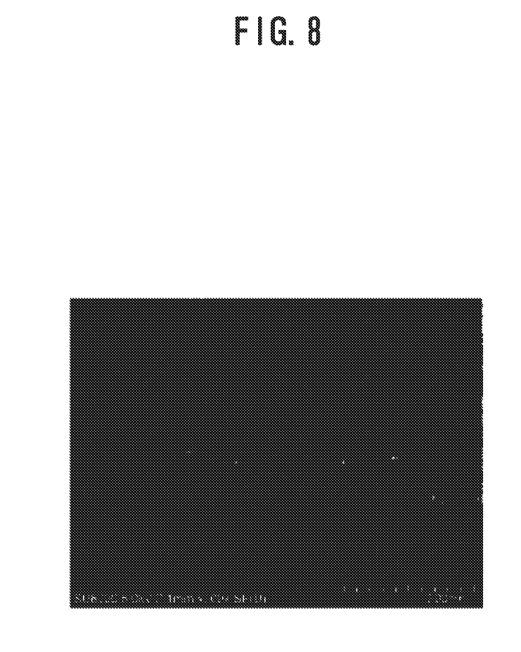

FIG. 8 is a part of an SEM image of a plurality of pairs of electrodes (initial nanogap electrodes 2A, 2B) fabricated on a silicon (Si) substrate 1A with a silicon dioxide (SiO2) film (insulating film 1B) using the EB lithographic technology. According to the SEM image, a gap separation of the initial electrodes (the metal layers 2A and 2B) is 30 nm.

Next, the SEM image is observed to measure the length of the nanogap electrodes fabricated in the example 1. The SEM image is obtained at a high resolution of 0.2 million times and resolution pixel is per 0.5 nm. In order to measure the length, the image is enlarged so that 1 pixel size can be evaluated and its contrast ratio is increased to clarify the difference between a gap region and the substrate 1 in the gap height and SEM characteristics.

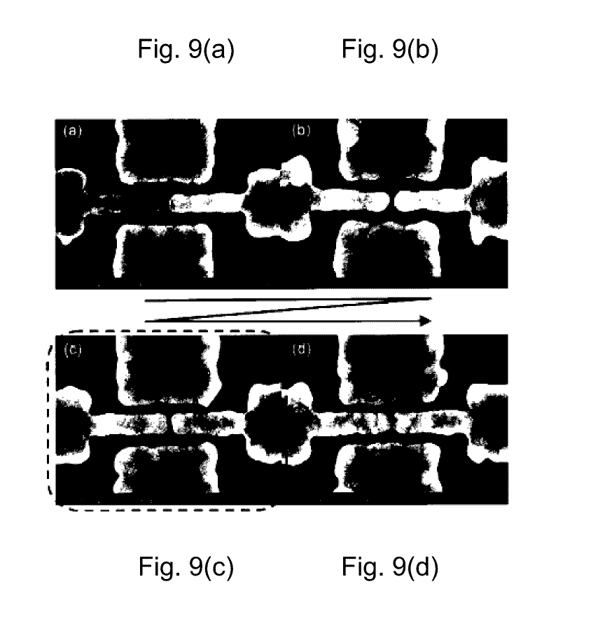

FIG. 9 is an SEM image of nanogap electrodes fabricated by dipping the substrate with initial nanogap electrodes shown in FIG. 8 in the molecular ruler plating solution. FIGS. 9 (a) to (d) are images respectively showing a part of pairs on one substrate.

As shown in FIG. 9 (c), gold is precipitated in the gap. A molecular ruler adhered to the gold surface inhibits the precipitation of the gold. The nanogaps with regular intervals and 5 nm width or more (in a crosswise direction) are extracted and measured.

FIG. 9 (a) shows electrodes with 5 nm or more gap separation and FIG. 9 (b) shows electrodes with 5 nm or less gap separation but their gap growth is not controlled. FIG. 9 (d) shows that the gap grows beyond inhibition of the molecular ruler and that metal layers 3A and 3B, i.e., a source electrode and a drain electrode, are connected to each other.

In this way, the average and the variance of respective measured molecular ruler are calculated. These data are used to calculate a normal distribution. Based on the histogram and the normal distribution of the measured data, a precise control of the gap separation of nanogap electrodes depending on the molecular length of the molecular ruler can be verified.

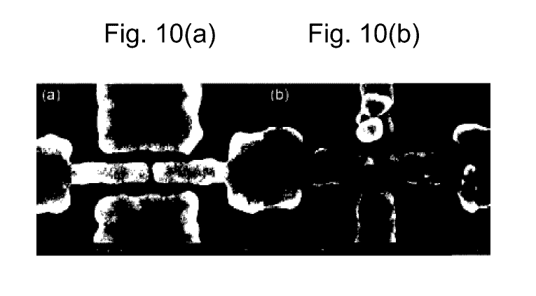

FIG. 10 is an SEM image showing an example of the nanogap electrodes fabricated in the example 1. The gap separation in FIG. 10 (a) and (b) are respectively 1.49 nm and 2.53 nm.

### EXAMPLE 2

In the example 2, nanogap electrodes are fabricated using the molecular ruler electroless plating method same as in the example 1 except for using LTAB molecule as alkyltrimethylammonium bromide.

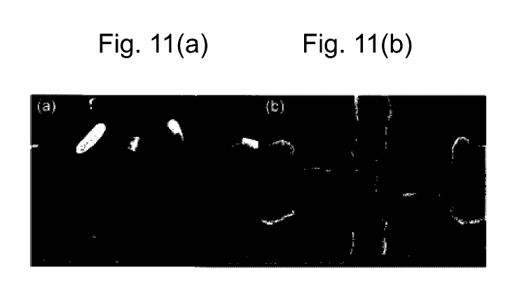

FIG. 11 is an SEM image showing an example of the nanogap electrodes fabricated in the example 2. The gap separation in FIG. 11 (a) and (b) are respectively 1.98 nm and 2.98 nm.

### EXAMPLE 3

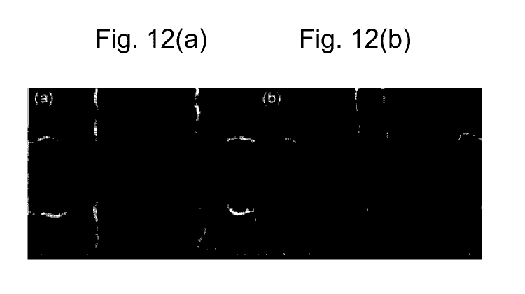

In the example 3, nanogap electrodes are fabricated using the molecular ruler electroless plating method same as in the example 1 except for using MTAB molecule as alkyltrimethylammonium bromide. FIG. 12 is an SEM image showing an example of the nanogap electrodes fabricated in the example 3. The gap separation in FIG. 12 (a) and (b) are respectively 3.02 nm and 2.48 nm.

### EXAMPLE 4

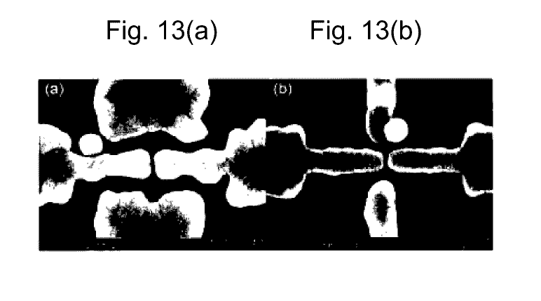

In the example 4, nanogap electrodes are fabricated using the molecular ruler electroless plating method same as in the example 1 except for using CTAB molecule as alkyltrimethylammonium bromide. FIG. 13 is an SEM image showing an example of the nanogap electrodes fabricated in the example 4. The gap separation in FIG. 13 (a) and (b) are respectively 3.47 nm and 2.48 nm.

The average and the standard deviation of the gap separation of the nanogap electrodes, fabricated in the examples 1 to 4, are calculated.

In the example 1, using DTAB molecule as a surfactant, the average gap separation and the standard deviation in the gap electrodes with 25 gap separations are respectively 2.31 nm and 0.54 nm.

In the example 2, using LTAB molecule as a surfactant, the average gap separation and the standard deviation in the gap electrodes with 44 gap separations are respectively 2.64 nm and 0.52 nm.

In the example 3, using MTAB molecule as a surfactant, the average gap separation and the standard deviation in the gap electrodes with 50 gap separations are respectively 3.01 nm and 0.58 nm.

In the example 4, using CTAB molecule as a surfactant, the average gap separation and the standard deviation in the gap electrodes with 54 gap separations are respectively 3.32 nm and 0.65 nm.

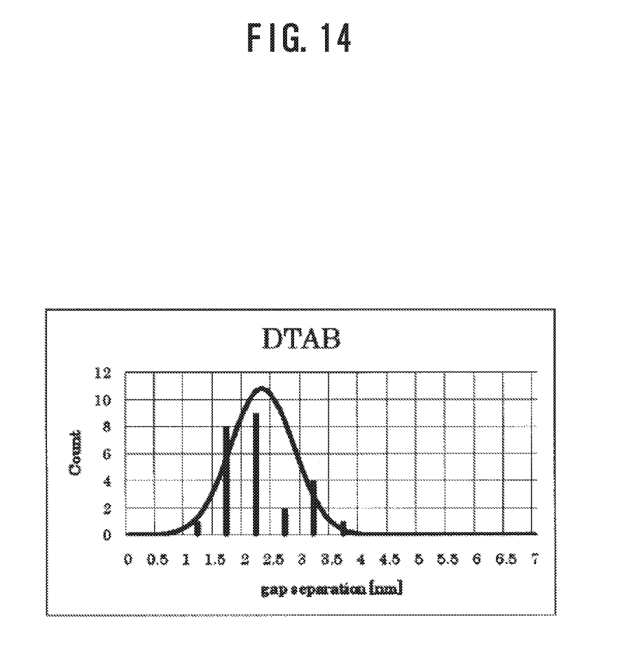

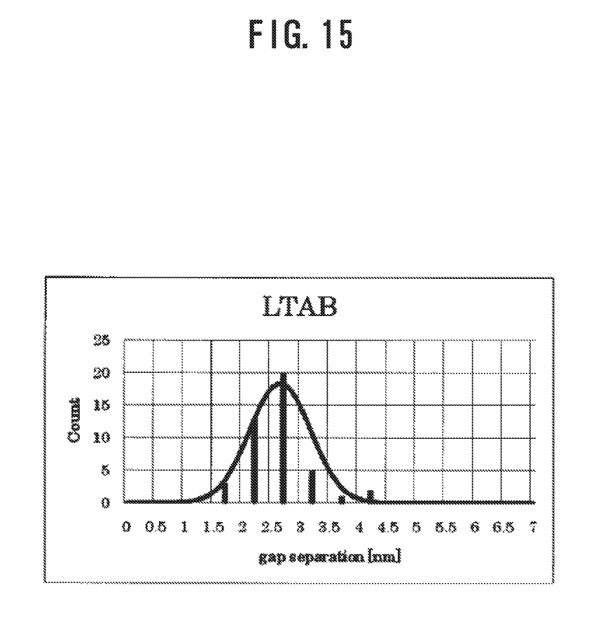

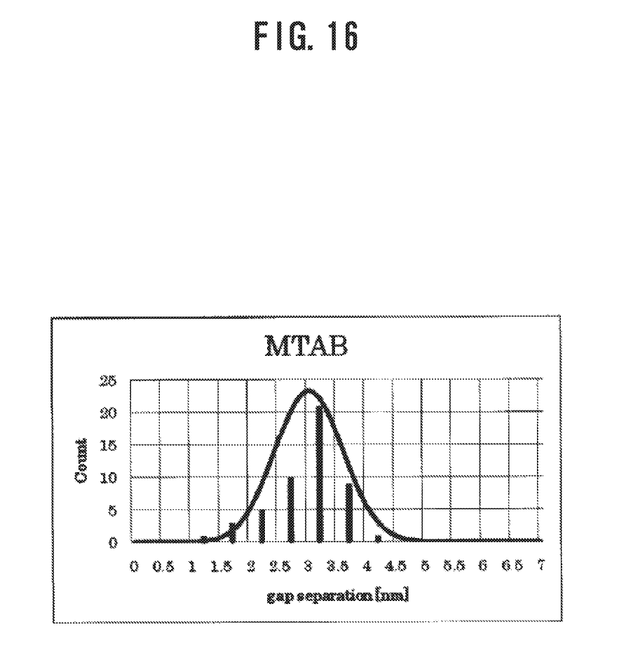

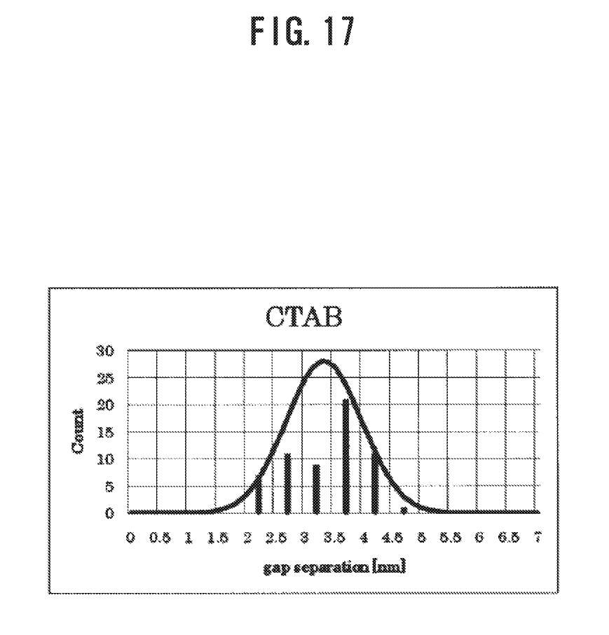

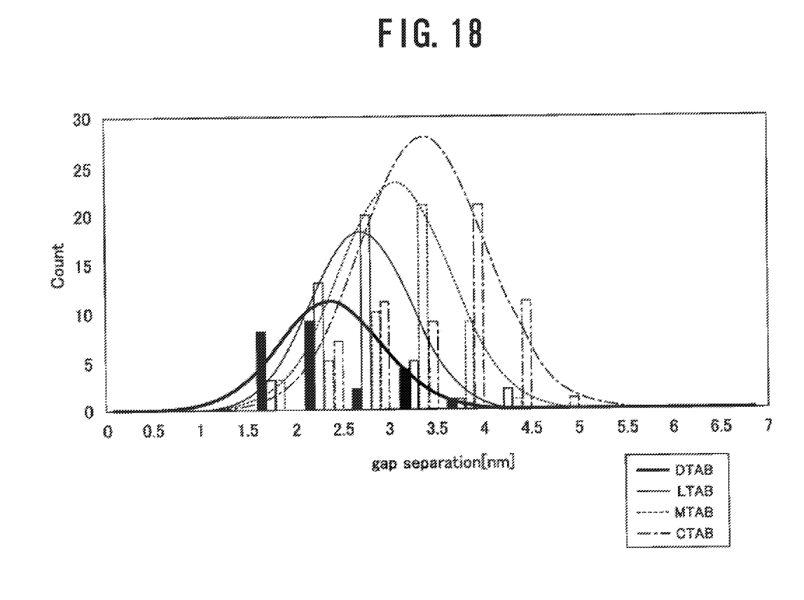

FIGS. 14 is a view showing a distribution of gap dispersion in the plurality of pairs of gap electrodes fabricated in the example 1. FIG. 15 is a view showing a distribution of gap dispersion in the plurality of pairs of gap electrodes fabricated in the example 2. FIGS. 16 is a view showing a distribution of gap dispersion in the plurality of pairs of gap electrodes fabricated in the example 3. FIGS. 17 is a view showing a distribution of gap dispersion in the plurality of pairs of gap electrodes fabricated in the example 4. FIG. 18 is a view overlaying histograms respectively shown in FIGS. 14 to 17. All the distributions are similar to the normal distribution.

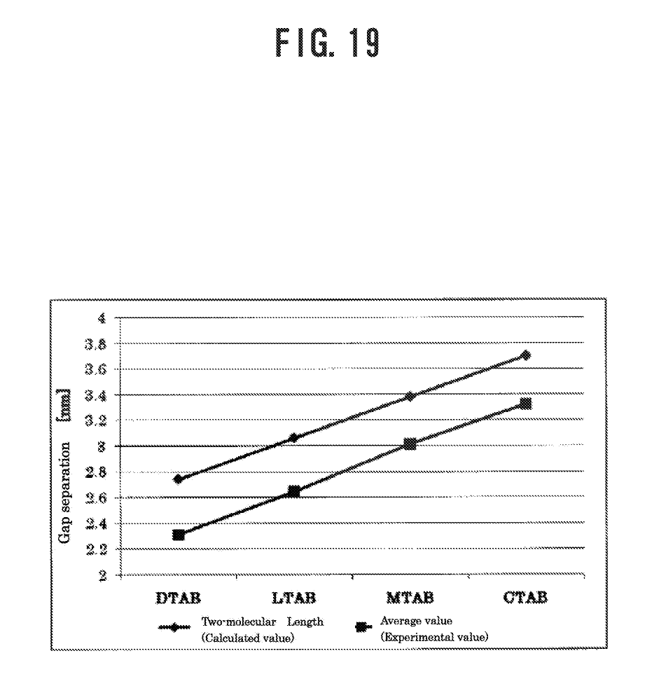

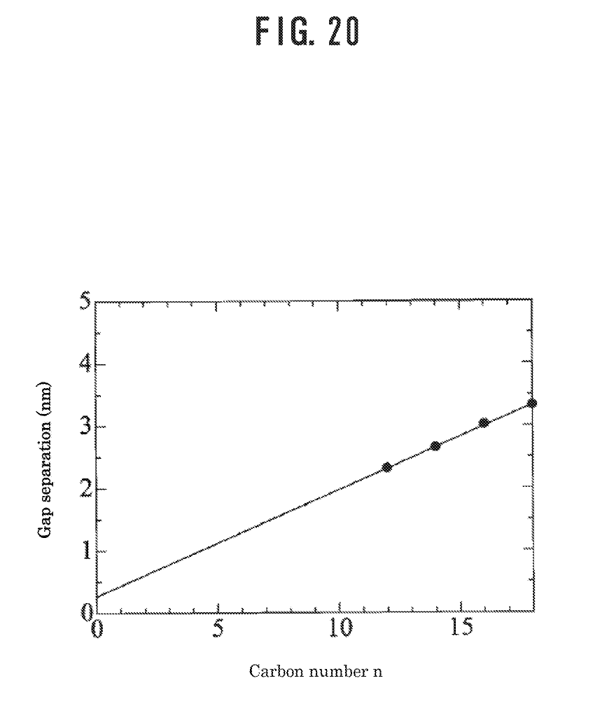

As shown in FIG. 18, there are 4 peaks of the average depending on the chain length. FIG. 19 is a graph plotting a two-chain length of surfactant molecules and the actual average. FIG. 20 is a view showing a relation between a carbon number n and a gap separation in the surfactant. These views show that the carbon number n is a linear relation with the gap separation. Specifically, it is found that the average gap separation is a linear relation with the carbon number of the surfactant. These facts indicate that the nanogap electrodes fabricated using the molecular ruler electroless plating method are controlled dependent on the chain length of the molecular ruler. Moreover, the average is about 0.4 nm under the two-particle chain length. It means that an interdigital engagement of one or two-alkyl chain length controls the growth of the nanogap electrodes, as shown in the schematic view of FIG. 3.

In the meantime, an electroless plating method with iodine enables fabricating nanogap electrodes with or less than 5 nm at 90% yield. The standard deviation is 1.37 nm.

As shown in the examples 1 to 4, in the electroless plating method using a molecular ruler, a surfactant adsorbed on a growing surface fills a nanogap. It provides an automatic stop of metal precipitation between the nanogap so that the gap separation is controlled based on a molecular length. Furthermore, the standard deviation of the gap separation is limited to 0.52 to 0.65 nm and it achieves a highly accurate control. However, the yield ratio is only about 10%. It is because the growth is very slower than when using an iodine tincture for plating which allows easy generation of clusters. The clusters adhere to an electrode portion and cause a high incidence of short out.

### EXAMPLE 5

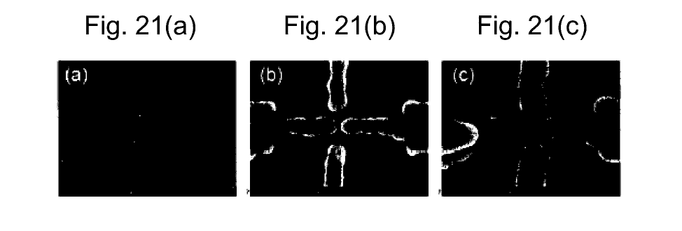

As described in the second embodiment of the present invention, a gold foil is dissolved in an iodine tincture solution as [AuI4]-ion. In this solution, L(+)-ascorbic acid is added to develop a self-catalytic plating on a gold electrode. Specifically, a self-catalytic iodine electroless plating method is used for plating initial nanogap electrodes fabricated by top-down approach, then after reducing the gap to some extent, a molecular ruler plating is performed for a shorter time. It inhibits generation of gold cluster, furthermore, it inhibits the cluster from adhering to the electrode surface, thereby suppressing a yield decrease of the nanogap electrodes. This enables a more accurate control of the nanogap separation at high yield. FIGS. 21 is an SEM image showing nanogap electrodes fabricated in the example 5. FIGS. 21 (a), 21(b), and 21(c) are SEM images respectively showing initial electrodes (23.9 nm), nanogap electrodes after the iodine plating (9.97 nm), and nanogap electrodes plated using DTAB as a molecular ruler (1.49 nm).

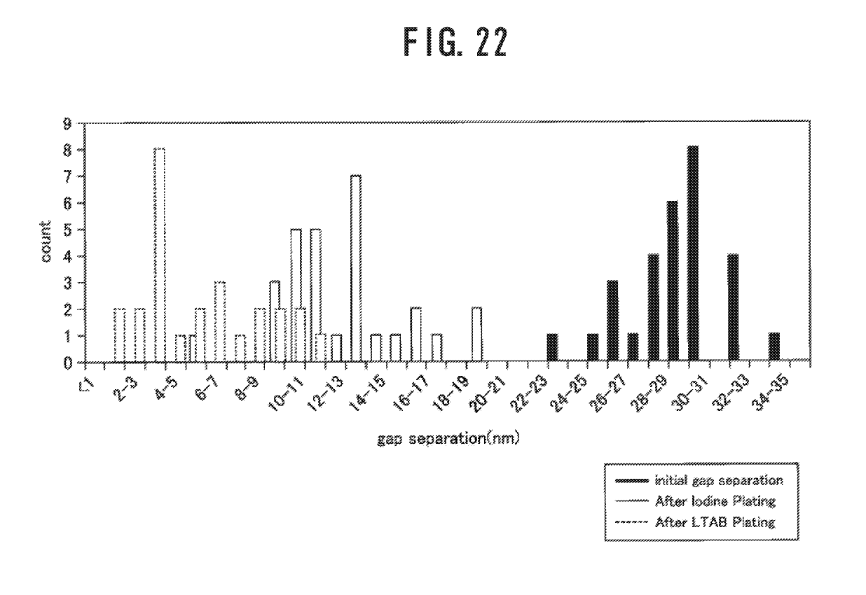

FIG. 22 is a view showing a histogram of nanogap electrodes at each stage of the fabrication in the example 5. The growth of nanogap electrodes automatically stops when the nanogap separation corresponds to the molecular ruler length. Specifically, a gap is controlled to keep a width of 5 nm or more at the regular intervals and the yield ratio of nanogap electrodes tremendously improves from 10% to 37.9%. Thus, it is found that a molecular ruler electroless plating after iodine electroless plating improves the yield ratio.

### EXAMPLE 6

A single-electron device is fabricated by introducing an Au nanoparticle between gold nanogap electrodes. Specifically, O2 plasma ashing is performed for the nanogap electrodes fabricated using the molecular ruler electroless plating method to ash molecules adhered to the surface. Next, a sample is dipped in a solution in which octanethiol (C85) is mixed with ethanol solution to be 1 mM for 12 hours and rinsed off with an ethanol twice. Then the sample is dipped in a solution in which decanedithiol (C10S2) is mixed with ethanol solution to be 5 mM for 7 hours and rinsed off with an ethanol twice. Thereafter, Au nanoparticle with decanethiol (C10S) protected are dispersed in toluene, dipped in a solution adjusted to have 0.5 mM concentration for 7 hours, and rinsed off with a toluene twice, then with an ethanol twice.

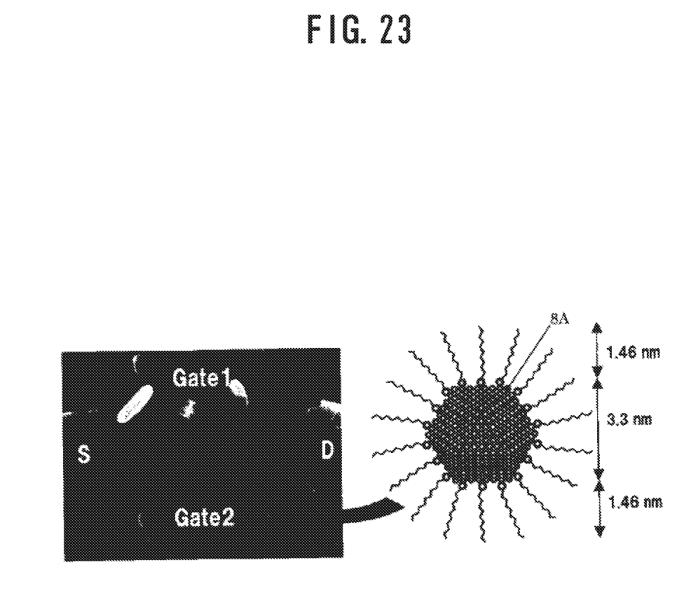

FIG. 23 is a view schematically showing a particle introduction of the single-electron device fabricated in the example 6. As shown in FIG. 23, the single-electron device has a first and second gate electrode (Gate 1, Gate 2) on the both sides at which a drain electrode (D) and a source electrode (5) are arranged, and C10-protected Au nanoparticle 8 are deposited between the nanogap, i.e., between the drain electrode and the source electrode.

The single-electron device fabricated in the example 6 has SAM (Self-Assembled Monolayer) tunnel junctions between electrodes 1, 2 and Au nanoparticle. It is equivalent that the electrodes 1, 2 are connected with Au nanoparticle via resistance and capacitance that are parallelly connected. The tunnel junction between the electrode 1 and the Au nanoparticle has a resistance called R1. The tunnel junction between the electrode 2 and the Au nanoparticle has a resistance called R2. Generally, these values R1, R2 may be affected by SAM, i.e., alkanethiol and alkanedithiol. The inventors of the present invention disclosed that the SAM resistance value approximately changes in single digit when a carbon number is changed for two (Non-Patent Literature 17, 18). Accordingly, based on the value of R1, R2, obtained using a theory fitting, it can be calculated which particle forms a junction.

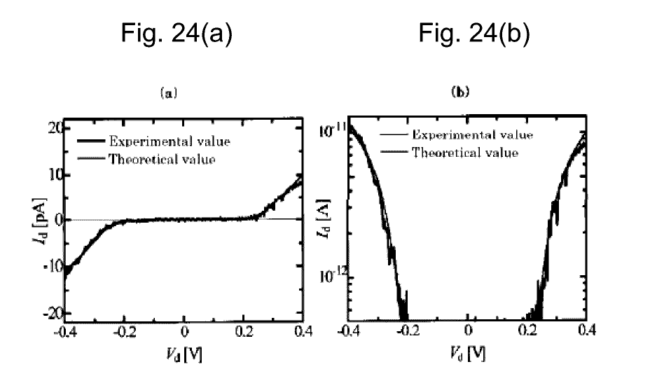

Current-voltage characteristics at liquid nitrogen temperature are measured without modulation by a gate electrode. FIG. 24 is a view showing current-voltage characteristics of electrodes 1 and 2 not modulated by the gate electrode; FIG. 24 (a) is a general view showing general current-voltage characteristics and (b) is its enlarged view. The figures indicate that no currency flows when a potential difference between a source electrode and a drain electrode (Vd) is about −0.2 V to 0.2 V. It is called as Coulomb blockade phenomena, caused by electron passing through a single-electron island with the tunnel junction, i.e., Au nanoparticles. Further, based on the theoretical value fitting, the values of R1 and R2 are respectively estimated as 6.0 and 5.9 G ohm, those may be octanethiol. It means that a particle introduction by chemical adsorption is not successful.

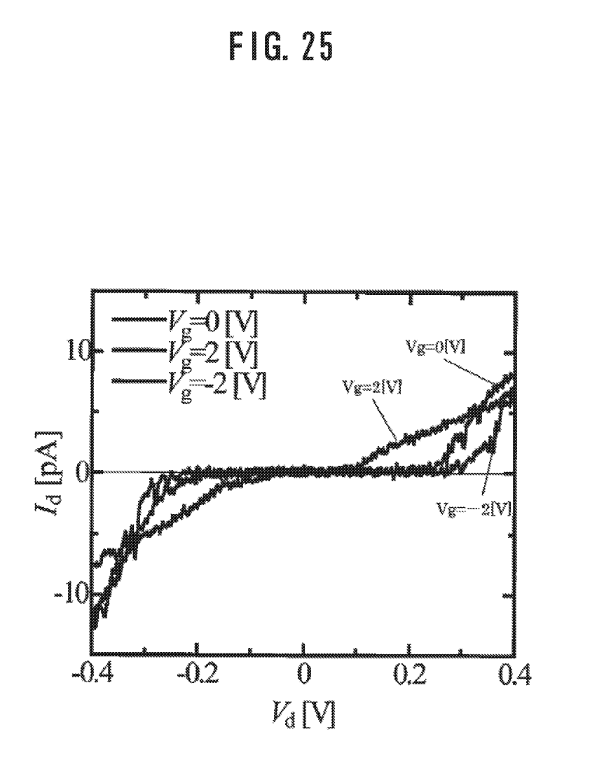

Next, the gate electrode performs modulation to measure current-voltage characteristics. FIG. 25 is a view showing current-voltage characteristics of the electrodes 1 and 2, not modulated by the gate electrode. The figure indicates a gate modulation effect, i.e., a gate modulation enables an easy introduction of electron to the gold single-electron island and a Coulomb blockade width changes. The single-electron device seems to leverage this modulation effect and have usefulness as an electrode. As shown in FIG. 25, it is possible to use a gate electrode for gate modulation and can be recognized that the electrodes are useful as a single-electron device.

### EXAMPLE 7

In the example 7, decamethoniumbromide is used as a surfactant. As in the example 1, initial gold nanogap electrodes are fabricated.

Next, an electroless plating solution is prepared. 28 mL of 25 mM decamethoniumbromide is measured to be used as a molecular ruler. Then, 120 μL of 50 mM gold trichloride acid solution is measured and added therein. 1 mL acetic acid as an acid and 3.6 mL of 0.1 mol L(+)-ascorbic acid as a reducing agent are added therein, and all are well stirred to be used as a plating solution.

The already fabricated substrate with gold nanogap electrodes is dipped in the electroless plating solution for about 30 minutes. Thereby, nanogap electrodes are fabricated using a molecular ruler electroless plating process in the example 7.

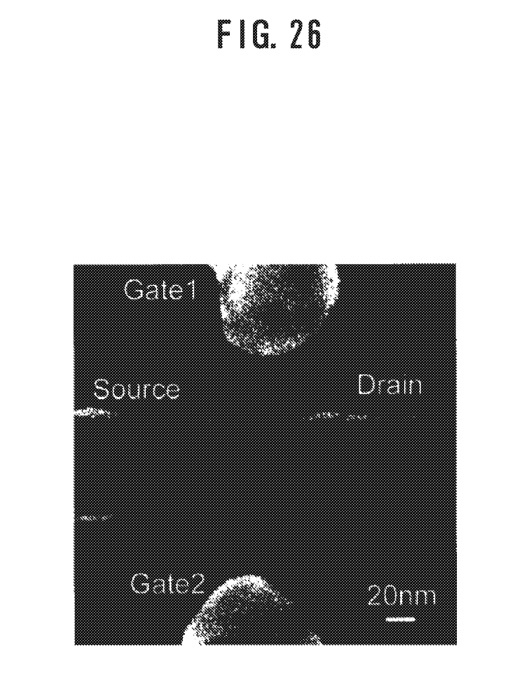

FIG. 26 is an SEM image of nanogap electrodes fabricated by dipping the substrate with initial nanogap electrodes in a molecular ruler plating solution. It indicates that the plating growth automatically stops when a gap separation reaches 1.6 nm.

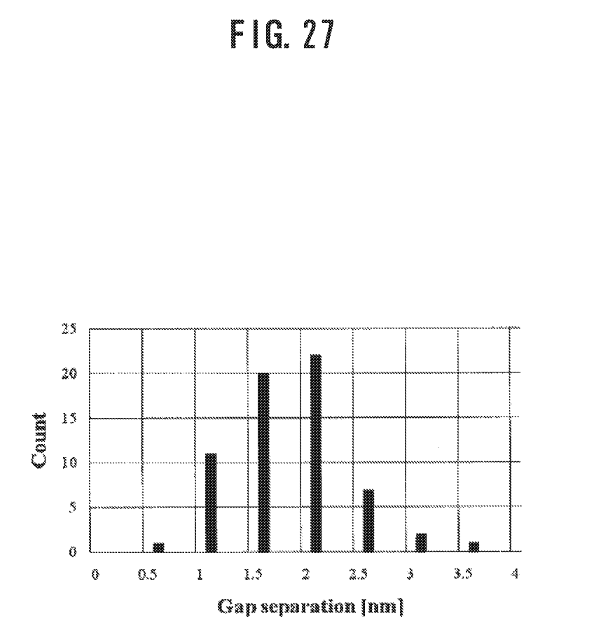

FIG. 27 is a view showing a histogram of the gap separation of the sample fabricated in the example 7. A horizontal and vertical axis respectively indicates a gap separation nm and a count. The average of the gap separation is 20 nm, smaller than those in the examples 1 to 4. There are 64 samples: the standard deviation is 0.56 nm; the minimum value is 1.0 nm; the median 2.0 nm; and the maximum value 3.7 nm.

A molecular length of decamethonium bromide, used as a surfactant in the example 7, is 1.61 nm and a molecular length of CTAB, used as a surfactant in the example 4, is 1.85 nm, i.e., the example 7 has a shorter molecular length and nanogap separation than the example 4. Therefore, it can be concluded that the molecular length of a surfactant enables a nanogap separation to be controlled.

The present invention is not limited to the embodiments and examples but can be modified in various ways within the scope of the inventions described in the claims, and needless to say, the modifications are included in the present invention.

### INDUSTRIAL AVAILABILITY

The nanogap electrodes are precisely controlled to have a very narrow gap separation between the electrodes using a molecular ruler electroless plating method of the present invention. Therefore, the nanogap electrodes shall play an important role in fabricating a nanodevice requiring nanogap electrodes, such as diode element, tunnel element, thermionic element, thermophotovoltaic element.

What is claimed is:

1. A nanodevice, comprising:
one and the other electrodes provided to have a nanogap;
a metal nanoparticle provided between the one and the other electrodes; and
a monolayer provided on at least the one and the other electrodes.

2. The nanodevice according to claim 1, wherein
the monolayer is a self-assembled monolayer.

3. The nanodevice according to claim 1, wherein
the metal nanoparticle is chemically adsorbed on the self-assembled monolayer.

4. The nanodevice according to claim 1, wherein
the monolayer comprises molecules, and
the metal nanoparticle is insulated from the one and the other electrodes by chemical bonding of alkanethiol as protecting group for the metal nanoparticle and a deficiency of a molecule.

5. The nanodevice according to claim 1, wherein
the one and the other electrodes are on the same plane, and
one or more side electrodes are provided on the plane.

6. The nanodevice according to claim 1, further comprising a passivation film.

7. A nanodevice, comprising:
one and the other electrodes provided to have a nanogap;
a metal nanoparticle provided between the one and the other electrodes; and
a monolayer provided between the metal nanoparticle and the one electrode and between the metal nanoparticle and the other electrodes; wherein
the metal nanoparticle is adsorbed at least on one and the other electrodes by alkanedithiol.

8. The nanodevice according to claim 7, wherein
the monolayer comprises alkanethiol.

9. The nanodevice according to claim 7, wherein
the monolayer is a self-assembled monolayer.

10. The nanodevice according to claim 7, wherein
the monolayer comprises molecules, and
the metal nanoparticle is insulated from the one and the other electrodes by chemical bonding of alkanethiol as protecting group for the metal nanoparticle and a deficiency of a molecule.

11. The nanodevice according to claim 7, wherein
the one and the other electrodes are on the same plane, and
one or more side electrodes are provided on the plane.

12. The nanodevice according to claim 7, further comprising a passivation film.
